(19) United States
(12) Patent Application Publication
(10) Pub. No.: US 2013/0214265 A1
(43) Pub. Date: Aug. 22, 2013

(54) SOLID-STATE IMAGING DEVICE AND IMAGING APPARATUS

(71) Applicant: FUJIFILM CORPORATION, (US)

(72) Inventor: Takashi GOTO, Ashigarakami-gun (JP)

(73) Assignee: FUJIFILM CORPORATION, Tokyo (JP)

(21) Appl. No.: 13/848,613

(22) Filed: Mar. 21, 2013

Related U.S. Application Data
(63) Continuation of application No. PCT/JP2011/064276, filed on Jun. 22, 2011.

(30) Foreign Application Priority Data
Sep. 27, 2010 (JP) 2010-216103

(51) Int. Cl. H01L 51/44

(52) U.S. Cl. CPC H01L 51/442
USPC 257/40

(57) ABSTRACT

A solid-state imaging device includes: plural pixel electrodes two-dimensionally arranged above a substrate; a counter electrode constituted of a transparent electrically conductive oxide having a resistance of not more than 100 kΩ/□, which is formed at an upper layer of the plural pixel electrodes; a light receiving layer including a photoelectric conversion layer containing an organic material, which is formed between the plural pixel electrodes and the counter electrode; and a connecting section for undergoing electrical connection between a voltage supply line for supplying a bias voltage to be impressed to the counter electrode, and in a plan view, a rectangular region in which the plural pixel electrodes are arranged is defined as a pixel region; the pixel region has a size of not more than 5 inches; the connecting section is formed as defined herein; and the counter electrode is formed as defined herein.

### TECHNICAL FIELD

The present invention relates to a solid-state imaging device and an imaging apparatus.

### BACKGROUND ART

In general solid-state imaging devices having a photodiode within a semiconductor substrate, the pixel size reaches the limits of microfabrication, and enhancements of performances such as sensitivity, etc. are becoming difficult. Then, there is proposed a high-sensitivity stack type solid-state imaging device in which a photoelectric conversion layer is provided above a semiconductor substrate so as to enable one to achieve an aperture ratio of 100% (see Patent Document 1).

The stack type solid-state imaging device described in Patent Document 1 has a configuration in which plural pixel electrodes are arranged and formed above the semiconductor substrate, one photoelectric conversion layer is formed above the plural pixel electrodes, and one counter electrode is formed above this photoelectric conversion layer. According to such a stack type solid-state imaging device, a bias voltage is impressed to the counter electrode to apply an electric field to the photoelectric conversion layer, a charge generated in the photoelectric conversion layer is moved to the pixel electrode, and a signal responsive to the charge is read out by a readout circuit connected to the pixel electrode.

The counter electrode is connected with a wiring for supplying a bias voltage. Since the counter electrode has a resistance value, in the counter electrode, the farther the position from a position at which the wiring is connected, the larger the voltage drop is. As a result, unevenness of the bias voltage to be impressed to the whole of the counter electrode is generated. This unevenness causes unevenness of a captured image (sensitivity unevenness), and hence, it lowers the captured image quality.

Such sensitivity unevenness can be minimized to such an extent that it can be theoretically ignored by choosing resistivities of the photoelectric conversion layer and the counter electrode, the size of a light receiving section where the plural pixel electrodes are disposed, and the like.

But, on the basis of such an ideal designed value, a stack type solid-state imaging device having such a configuration in which a photoelectric conversion layer is configured to contain an organic material, a counter electrode is constituted of a transparent electrically conductive oxide, a connecting section for electrically connecting a wiring to be connected with a voltage supply section for supplying a bias voltage and the counter electrode to each other is provided so as to come into contact with the counter electrode, and a bias voltage is impressed to the counter electrode via this connecting section was fabricated. As a result, it was noted that sensitivity unevenness which should not be generated from the theoretical standpoint was generated depending upon the disposition of the connecting section.

It may be considered that this sensitivity unevenness is generated due to various factors such as a resistance value of the connecting section, irregularities of the surface, which are formed at the time of manufacture of a pixel electrode, the fact that the photoelectric conversion layer is made of an organic material, etc. But, a factor thereof is not certain.

Patent Document 1 does not describe a specific configuration for impressing a bias voltage to the counter electrode and does not give any description regarding a method for dismissing the sensitivity unevenness generated due to the foregoing various factors.

In addition, Patent Document 2 discloses a configuration in which a bias voltage supply line is connected to two diagonal points of a rectangular counter electrode included in a stack type solid-state imaging device. But, in Patent Document 2, the photoelectric conversion layer is constituted of an inorganic material, and Patent Document 2 does not concern with the configuration where the foregoing various factors are generated. In addition, Patent Document 2 does not specifically describe a method for connecting a bias voltage supply line to the counter electrode for the purpose of dismissing the sensitivity unevenness generated due to the foregoing various factors.

### PRIOR ART DOCUMENT

### Patent Document

Patent Document 1: JP-A-2008-263178
Patent Document 2: JP-A-2002-236054

### SUMMARY OF THE INVENTION

### Problem to be Solved by the Invention

In view of the foregoing circumstances, the present invention has been made, and an object thereof is to provide a solid-state imaging device capable of enhancing the captured image quality and an imaging apparatus.

### Means for Solving the Problem

The solid-state imaging device according to the present invention comprises plural pixel electrodes two-dimensionally arranged above a substrate; a counter electrode constituted of a transparent electrically conductive oxide having a resistance of not more than 100 kΩ/□, which is formed at an upper layer of the plural pixel electrodes; a light receiving layer including a photoelectric conversion layer containing an organic material, which is formed between the plural pixel electrodes and the counter electrode; and a connecting section for undergoing electrical connection between a voltage supply line for supplying a bias voltage to be impressed to the counter electrode, wherein in a plan view, a rectangular region in which the plural pixel electrodes are arranged is defined as a pixel region; the pixel region has a size of not more than 5 inches; the connecting section is formed in a region which is a peripheral region outside the pixel region and which is made in the vicinity of at least one side among four sides of the pixel region and along the one side, or in a region in the vicinity of at least two corners among four corners of the pixel region; and the counter electrode is formed extending to above the connecting section.

According to this configuration, the sensitivity unevenness generated due to factors other than the voltage drop of the counter electrode can be suppressed.

The imaging apparatus according to the present invention comprises the foregoing solid-state imaging device.

### Effect of the Invention

According to the present invention, it is possible to provide a solid-state imaging device capable of enhancing the captured image quality and an imaging apparatus.

### BRIEF DESCRIPTION OF THE DRAWINGS

FIG. 1 is a plan schematic view showing a diagrammatic configuration of a solid-state imaging device for explaining an embodiment of the present invention.

FIG. 2 is an A-A line cross-sectional schematic view in a solid-state imaging device 1 shown in FIG. 1.

FIG. 3 is a graph showing a relation between film thickness and transmittance of ITO.

FIG. 4 is a graph showing a relation between bias voltage and sensitivity in an organic photoelectric conversion device using an organic material in a photoelectric conversion layer.

FIG. 5 is a view showing an example of disposition of a connecting section in which the sensitivity unevenness is reduced in the solid-state imaging device shown in FIG. 1.

FIG. 6 is a view showing an example of disposition of a connecting section in which the sensitivity unevenness is reduced in the solid-state imaging device shown in FIG. 1.

FIG. 7 is a view showing an example of disposition of a connecting section in which the sensitivity unevenness is reduced in the solid-state imaging device shown in FIG. 1.

FIG. 8 is a view showing an example of disposition of a connecting section in which the sensitivity unevenness is reduced in the solid-state imaging device shown in FIG. 1.

FIG. 9 is a view showing an example of disposition of a connecting section in which the sensitivity unevenness is reduced in the solid-state imaging device shown in FIG. 1.

FIG. 10 is a view showing an example of disposition of a connecting section in which the sensitivity unevenness is reduced in the solid-state imaging device shown in FIG. 1.

FIG. 11 is a view showing an example of disposition of a connecting section in which the sensitivity unevenness is reduced in the solid-state imaging device shown in FIG. 1.

FIG. 12 is a view showing an example of a configuration of a light receiving layer of the solid-state imaging device shown in FIG. 1.

### MODES FOR CARRYING OUT THE INVENTION

Embodiments of the present invention are hereunder described with reference to the accompanying drawings.

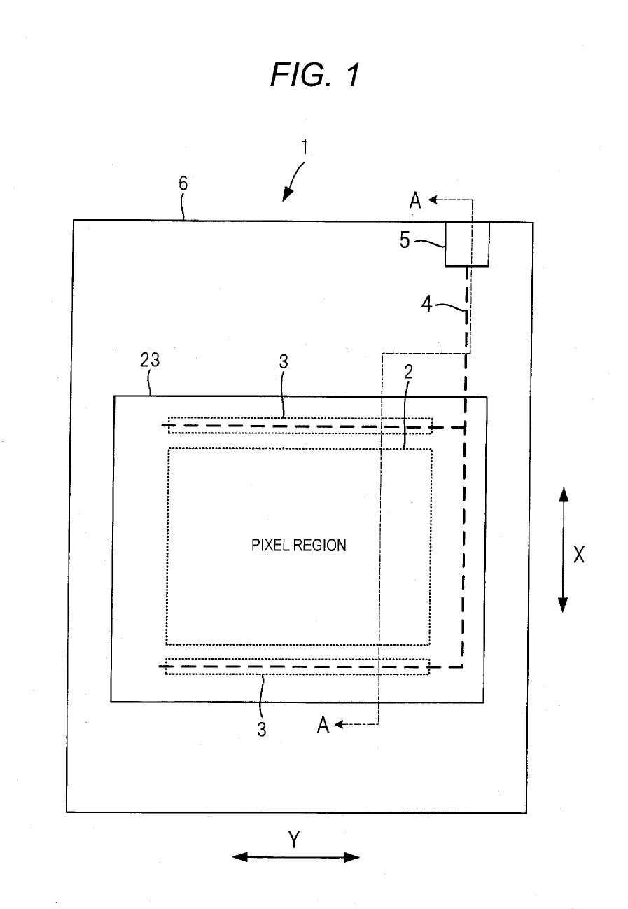

FIG. 1 is a plan schematic view showing a diagrammatic configuration of a solid-state imaging device for explaining an embodiment of the present invention. A solid-state imaging device 1 shown in FIG. 1 is provided with a rectangular pixel region 2 and a peripheral region other than that. In the peripheral region, two connecting sections 3, details of which are described later, are formed. In the pixel region 2 and a part of the peripheral region, a counter electrode 23 is formed.

In the peripheral region, a voltage supply section 5 for supplying a bias voltage to the counter electrode 23 is formed, and the voltage supply section 5 is connected with a bias voltage supply line 4. This bias voltage supply line 4 is formed extending beneath each of the two connecting sections 3. The bias voltage supply line 4 is electrically connected to the connecting section 3 with a non-illustrated plug beneath the connecting section 3.

The pixel region 2 is a region in which plural photoelectric conversion devices are arranged in a two-dimensional form (for example, a square lattice form) in a horizontal direction Y and a vertical direction X orthogonal thereto.

In the pixel region 2, plural pixel electrodes are two-dimensionally arranged above a semiconductor substrate 6, a light receiving layer of a single-sheet configuration is formed above the whole of the plural pixel electrodes, and the counter electrode 23 of a single-sheet configuration is formed above this light receiving layer. A photoelectric conversion device is configured by each of the pixel electrodes and the counter electrode 23 opposing thereto and the light receiving layer located between these electrodes.

The connecting section 3 is one contriving to undergo electrical connection between the counter electrode 23 and the bias voltage supply line 4 and is formed of an electrically conductive material. In the example of FIG. 1, in the peripheral region of the solid-state imaging device 1, the connecting section 3 is formed in such a manner that it is made adjacent to each of two sides extending to the horizontal direction Y among four sides of the pixel region 2 and alone these two sides.

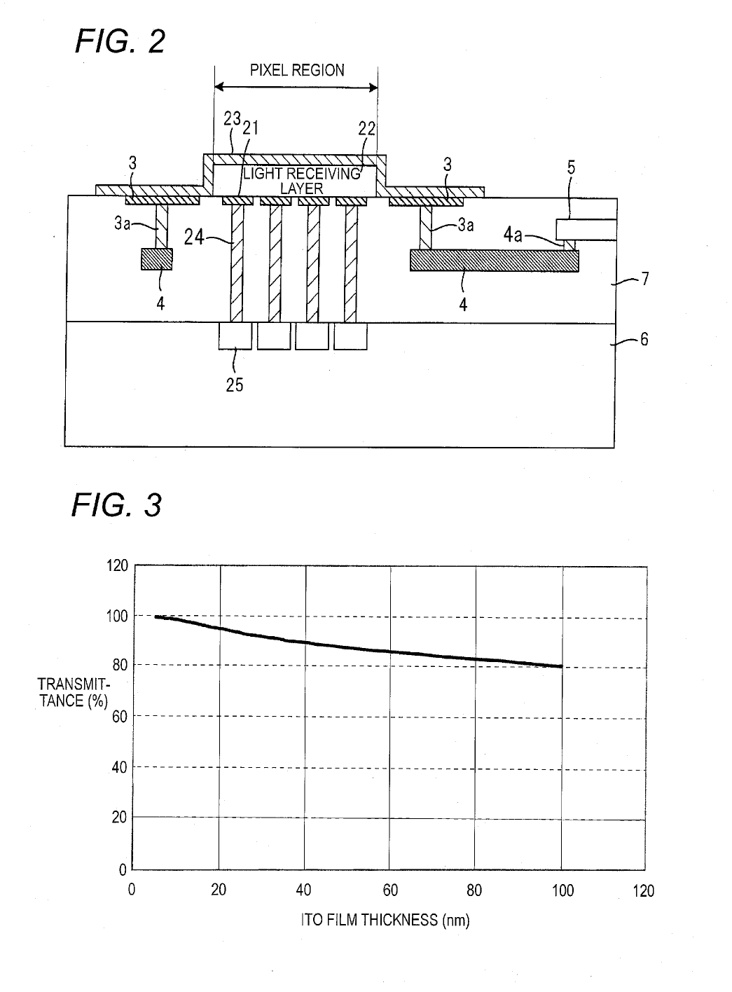

FIG. 2 is an A-A line cross-sectional schematic view in the solid-state imaging device 1 shown in FIG. 1.

As shown in FIG. 2, an insulating layer 7 is formed above the semiconductor substrate 6. In the pixel region 2, pixel electrodes 21 are two-dimensionally arranged and formed on a surface of the insulating layer 7, and one light receiving layer 22 is formed above the plural pixel electrodes 21. The counter electrode 23 is formed above the light receiving layer 22, and the counter electrode 23 is formed not only in the pixel region 2 but extending to above the insulating layer 7 located in the peripheral region outside the pixel region 2.

The light receiving layer 22 includes at least a photoelectric conversion layer, and this photoelectric conversion layer is configured to contain an organic material.

In the solid-state imaging device 1, resistance values of the light receiving layer 22 and the counter electrode 23 and the size of the pixel region 2 where the plural pixel electrodes 21 are disposed are chosen such that a voltage drop to be caused due to a distance from a supply point (the connecting section 3 in the example of FIG. 1) of a bias voltage to the counter electrode 23 becomes small to a negligible extent.

Specifically, not only the size of the pixel region 2 (length of a diagonal line of the rectangle) is not more than 5 inches, but a ratio in the resistance value between the light receiving layer 22 and the counter electrode 23 is double-digit or more. When a practical material is used, the resistance value of the light receiving layer 22 is at least 10 MΩ/□ or more. Accordingly, more specifically, not only the size of the pixel region 2 is not more than 5 inches, but the resistance value of the counter electrode 23 is not more than 100 kΩ/□.

The pixel electrode 21 is an electrode for collecting charges which are generated in the photoelectric conversion layer included in the light receiving layer 22. It may be sufficient that the pixel electrode 21 is constituted of an electrically conductive material. The pixel electrode 21 is preferably constituted so as to contain at least one of TiN, W, Cr, ITO, Al, Cu, and AlCu.

The counter electrode 23 is constituted of a transparent electrically conductive oxide. As the transparent electrically conductive oxide, ITO can be preferably used.

FIG. 3 is a graph showing a relation between film thickness and transmittance of ITO. In order to increase the sensitivity, it is desirable that the transmittance of the counter electrode 23 is 95% or more, and preferably 98% or more. Accordingly, in the case where ITO is used as the counter electrode, from the data shown in FIG. 3, it is desirable that its film thickness is not more than 20 nm (preferably 10 nm).

In the semiconductor substrate 6 within the pixel region 2, a readout circuit 25 is formed corresponding to the respective pixel electrode 21.

The readout circuit 25 is one for reading out a signal responsive to the charge collected by the corresponding pixel electrode 21, and it is constituted of, for example, a CCD or MOS circuit or the like. In the case where a glass substrate or the like is used in place of the semiconductor substrate 6, the readout circuit 25 may be constituted of a TFT circuit.

The respective pixel electrode 21 and the readout circuit 25 corresponding thereto are electrically connected to each other by an electrically conductive plug 24 embedded within the insulating layer 7.

In FIG. 2, the connecting section 3 is formed in the same layer as the pixel electrode 21 in the peripheral region neighboring to each of the right and the left of the pixel region 2. Though it may be sufficient that the connecting section 3 is constituted of an electrically conductive material, it is preferable that the connecting section 3 is configured to contain the same electrically conductive material as the electrically conductive material contained in the pixel electrode 21. By taking such a configuration, the connecting section 3 and the pixel electrode 21 can be simultaneously formed, and a manufacturing step can be simplified.

The connecting section 3 is formed beneath the counter electrode 23 formed in the peripheral region and comes into direct contact with the counter electrode 23. The connecting section 3 impresses a bias voltage to be supplied from the bias voltage supply line 4 to the counter electrode 23.

In a lower layer than the connecting section 3, the bias voltage supply line 4 with low resistance is formed. The connecting section 3 and the bias voltage supply line 4 are electrically connected to each other by an electrically conductive plug 3a provided beneath the connecting section 3. Incidentally, the connecting section 3 has a long and narrow shape in the horizontal direction Y. Accordingly, the bias voltage supply line 4 and the connecting section 3 may also be connected to each other by the electrically conductive plugs 3a in plural places of the connecting section 3 such that a bias voltage is stably supplied to the counter electrode 23.

In an upper layer than the bias voltage supply line 4, a voltage supply section 5 is formed. The voltage supply section 5 is one for supplying a bias voltage that is higher than a power supply voltage of the readout circuit 25 formed in the semiconductor substrate 6.

For example, the voltage supply section 5 is constituted of a booster circuit for boosting the power supply voltage of the readout circuit 25 formed in the semiconductor substrate 6 to produce a bias voltage. There may be taken a configuration in which an electrode pad capable of being electrically connected from the outside of the solid-state imaging device 1 is formed as the voltage supply section 5, and a bias voltage that is higher than the foregoing power supply voltage is supplied to this electrode pad from an external power supply of the solid-state imaging device 1.

A difference between a potential in an output terminal of this voltage supply section 5 and a potential in a connecting portion of the connecting section 3 to the bias voltage supply line 4 is preferably made to be not more than 0.1 V. It is preferable to determine the resistance value or wiring length, or the like of the bias voltage supply line 4 so as to reveal such a value. In order to contrive to achieve low resistance, the bias voltage supply line 4 may be constituted of a multilayer wiring.

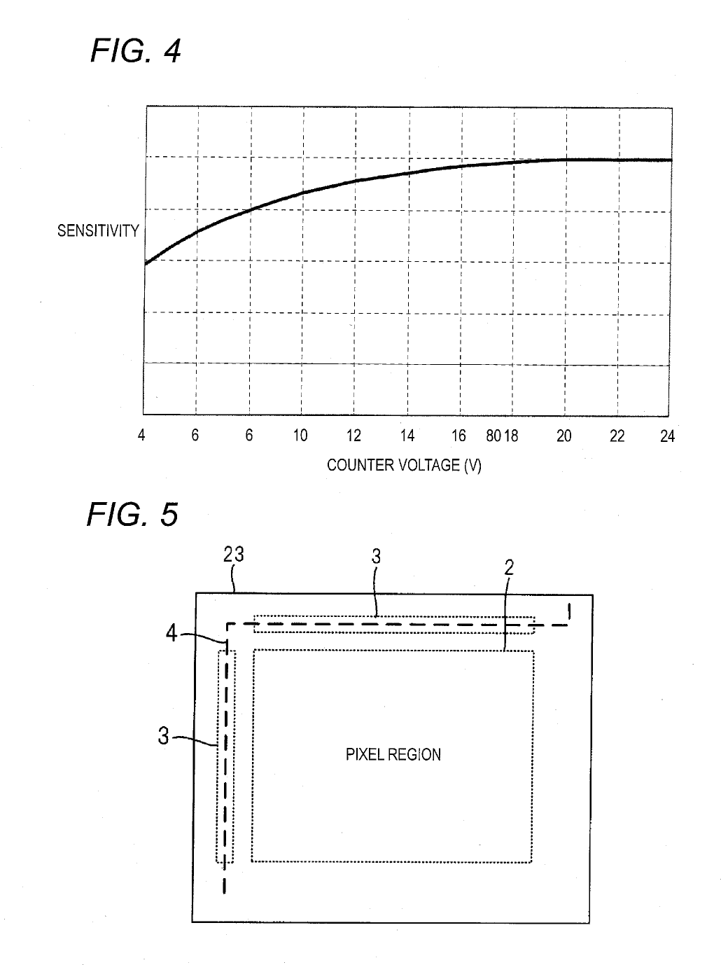

FIG. 4 is a graph showing a relation between bias voltage and sensitivity in an organic photoelectric conversion device using an organic material in a photoelectric conversion layer. In FIG. 4, data in the case of collecting holes by the pixel electrode were shown.

As shown in FIG. 4, the larger the bias voltage (counter voltage) to be impressed to the counter electrode, the higher the sensitivity of the organic photoelectric conversion device is. But, this sensitivity is saturated at 20 V or more. Though this characteristic is also scattered depending upon a material of the light receiving layer or the like, when the bias voltage is 30 V or more, the sensitivity of almost all of devices is saturated.

Incidentally, in the case of collecting electrons by the pixel electrode, when the bias voltage is not more than −30 V, the sensitivity of almost all of devices is saturated. Accordingly, as for the bias voltage supplied by the voltage supply section 5, a value in the range of from 0 V to 30 V may be chosen so far as holes are read out as signals, whereas a value in the range of from −30 V to 0 V may be chosen so far as electrons are read out as signals.

According to the solid-state imaging device 1 having the foregoing configuration, even in a configuration in which the counter electrode 23 is constituted of a transparent electrically conductive oxide, a layer containing an organic material is used as the photoelectric conversion layer, and a bias voltage is supplied to the counter electrode 23 via the connecting section 3, sensitivity unevenness to be caused due to other factor than that in the sensitivity unevenness by a voltage drop to be caused due to a distance from a supply point (the connecting section 3 in the example of FIG. 1) of a bias voltage to the counter electrode 23 can be suppressed to a low level.

Incidentally, even when the configuration of the connecting section 3 is one as described below, the foregoing sensitivity unevenness to be caused due to other factor as described above can be suppressed.

For example, by taking a configuration shown in FIG. 5, in which the connecting sections 3 are provided in regions adjacent to two sides which are adjacent to each other among four sides of the pixel region 2 and extending along these two sides in the peripheral region, the sensitivity unevenness can be similarly suppressed.

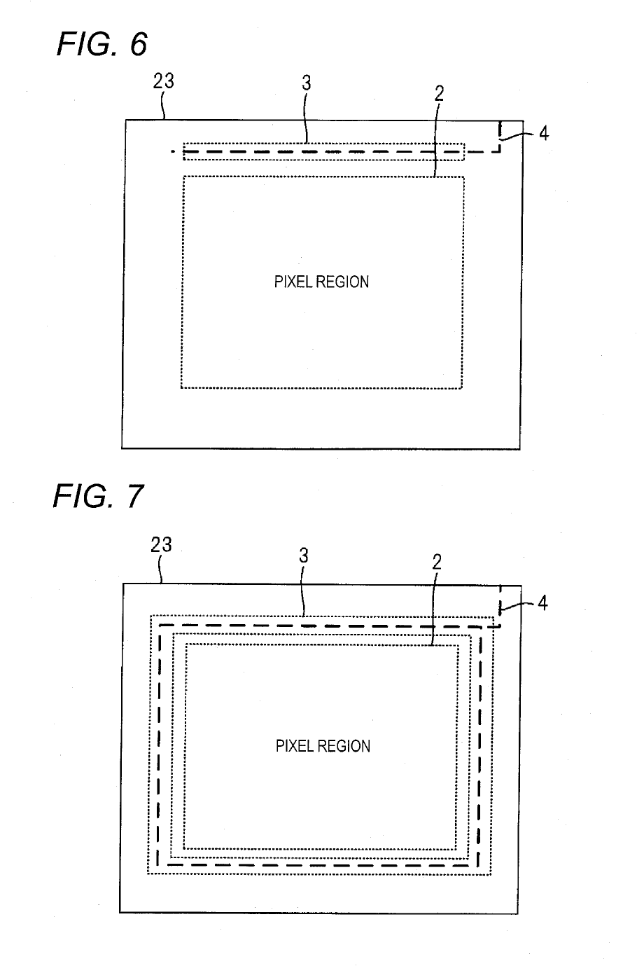

In addition, by taking a configuration shown in FIG. 6, in which the connecting section 3 is provided only in a region adjacent to one side of four sides of the pixel region 2 and extending along this one side in the peripheral region, the sensitivity unevenness can be similarly suppressed.

In addition, by taking a configuration (not shown), in which the connecting sections 3 are provided in regions adjacent to three sides among four sides of the pixel region 2 and extending along these three sides in the peripheral region, the sensitivity unevenness can be similarly suppressed.

In addition, by taking a configuration shown in FIG. 7, in which the connecting sections 3 are provided in regions adjacent to all of sides among four sides of the pixel region 2 and extending along these four sides in the peripheral region, the sensitivity unevenness can be similarly suppressed.

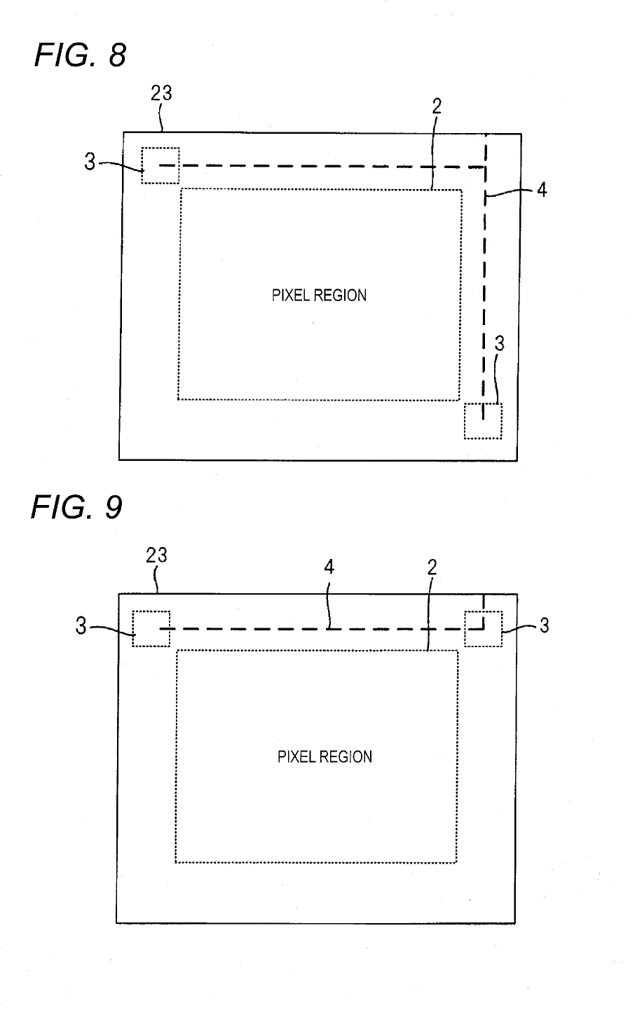

In addition, by taking a configuration shown in FIG. 8, in which the connecting section 3 is provided in a region in the vicinity of each of two corners which are diagonal to each other among four corners of the pixel region 2 in the peripheral region, the sensitivity unevenness can be similarly suppressed.

In addition, by taking a configuration shown in FIG. 9, in which the connecting section 3 is provided in a region in the vicinity of each of two corners which are adjacent to each other among four corners of the pixel region 2 in the peripheral region, the sensitivity unevenness can be similarly suppressed.

In addition, by taking a configuration (not shown), in which the connecting section 3 is provided in a region in the vicinity of each of three corners among four corners of the pixel region 2 in the peripheral region, the sensitivity unevenness can be similarly suppressed.

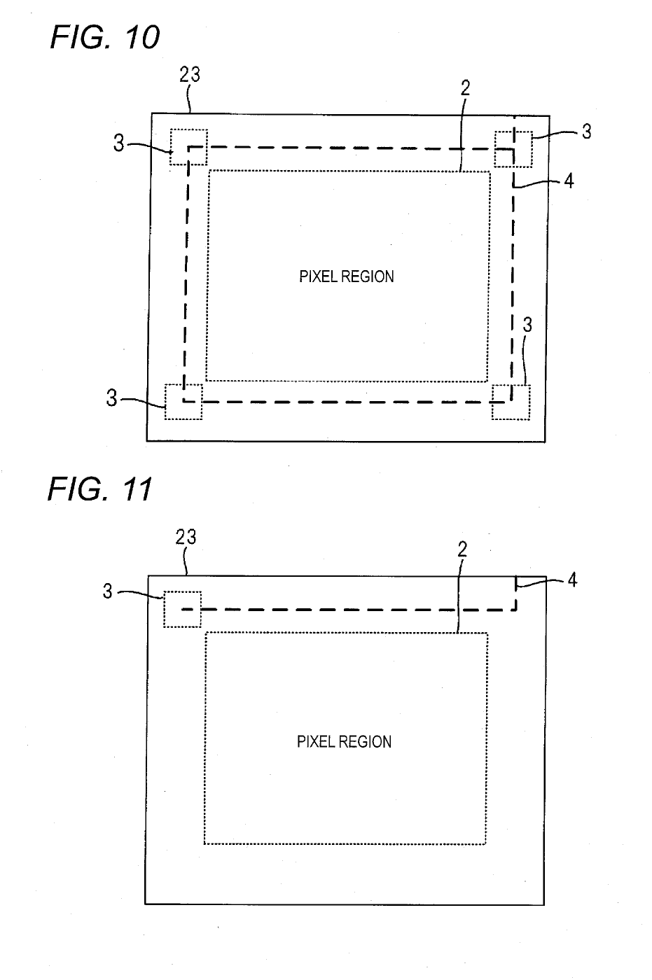

In addition, by taking a configuration shown in FIG. 10, in which the connecting section 3 is provided in a region in the vicinity of each of all of corners among four corners of the pixel region 2 in the peripheral region, the sensitivity unevenness can be similarly suppressed.

On the other hand, in a configuration shown in FIG. 11, in which the connecting section 3 is provided in only a region in the vicinity of one corner among four corners of the rectangle of the pixel region 2 in the peripheral region, the sensitivity unevenness becomes large to an extent that it is problematic from the standpoint of practical use.

In this way, by taking a configuration in which the connecting section 3 is provided in a region adjacent to at least one side among four sides of the pixel region 2 and extending along this at least one side, or a configuration in which the connecting section 3 is provided in a region in the vicinity of each of at least two corners among four corners of the pixel region 2, in the peripheral region, the sensitivity unevenness can be improved to a level at which it is not problematic from the standpoint of practical use.

Incidentally, it may also be considered that the foregoing sensitivity unevenness is generated due to a factor of the fact that the pixel electrode 21 and the connecting section 3 are simultaneously formed, thereby making them identical with each other in terms of the material and thickness. In consequence, the present invention is especially effective for solid-state imaging devices in which the pixel electrode 21 and the connecting section 3 are made identical with each other in terms of the material and film thickness.

In addition, there is taken a configuration in which the connecting section 3 of the solid-state imaging device 1 is formed in the same layer as the pixel electrode 21, and in order to bring the counter electrode 23 into contact with this connecting section 3, the counter electrode 23 also covers a side wall of the light receiving layer 22. It may also be considered that other factor of the sensitivity unevenness than the voltage drop of the counter electrode 23 is generated due to such a configuration. Accordingly, the present invention is especially effective for solid-state imaging devices having a configuration in which the counter electrode 23 comes into contact with the side wall of the light receiving layer 22.

In addition, in the solid-state imaging device 1, the bias voltage to be impressed to the counter electrode 23 is low as from 0 to 30 V in terms of an absolute value. Accordingly, as compared with devices in which a large bias voltage of from 5,000 to 15,000 V, as in the device described in Patent Document 2, a change of the bias voltage is also liable to influence the sensitivity unevenness. In consequence, it is effective to adopt the configuration according to the present invention.

A preferred configuration of the light receiving layer 22 is hereunder described.

### <Light Receiving Layer>

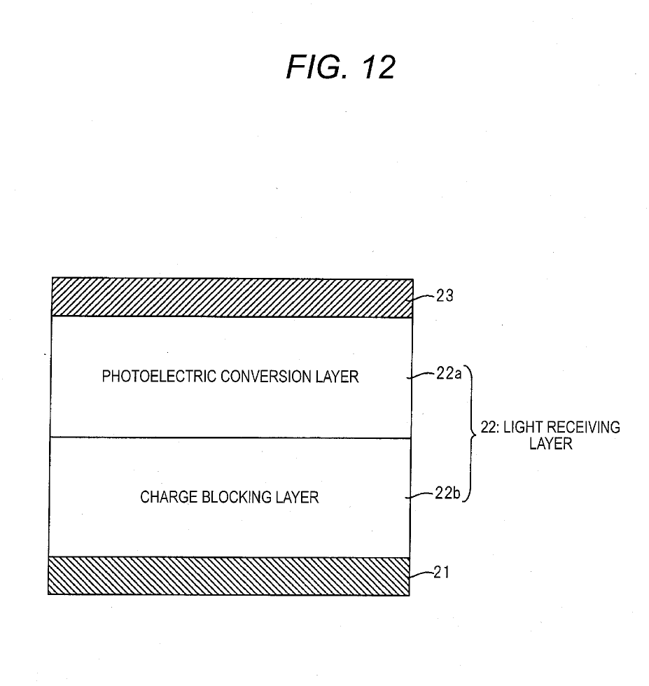

FIG. 12 is a cross section showing an example of a configuration of the light receiving layer 22. As shown in FIG. 12, the light receiving layer 22 includes a charge blocking layer 22b formed on the pixel electrode 21 and a photoelectric conversion layer 22a formed on the charge blocking layer 22b.

The charge blocking layer 22b has a function to suppress a dark current. The charge blocking layer may be constituted of plural layers. In this way, when the charge blocking layer 22b is constituted of plural layers, an interface is formed between the plural charge blocking layers, and discontinuity is generated in an intermediate level existing in each of the layers. Charge carriers hardly move via this intermediate level, and the dark current can be strongly suppressed.

The photoelectric conversion layer 22a contains a p-type organic semiconductor and an n-type organic semiconductor. By joining the p-type organic semiconductor and the n-type organic semiconductor to form a donor/acceptor interface, exciton dissociation efficiency can be increased. Accordingly, the photoelectric conversion layer 22a having a configuration in which the p-type organic semiconductor and the n-type organic semiconductor are joined reveals high photoelectric conversion efficiency. In particular, the photoelectric conversion layer 22a in which the p-type organic semiconductor and the n-type organic semiconductor are mixed is preferable because the joined interface increases, whereby the photoelectric conversion efficiency is enhanced.

The p-type organic semiconductor (compound) is an organic semiconductor with donor properties and refers to an organic compound chiefly represented by a hole transporting organic compound and having such properties that it is liable to donate electrons. In more detail, when two organic materials are brought into contact with each other and used, an organic compound having a smaller ionization potential is referred to as the p-type organic semiconductor. In consequence, as for the organic compound with donor properties, any organic compounds can be used so far as they are an organic compound with electron donating properties. For example, metal complexes having, as a ligand, a triarylamine compound, a benzidine compound, a pyrazoline compound, a styrylamine compound, a hydrazone compound, a triphenylmethane compound, a carbazole compound, a polysilane compound, a thiophene compound, a phthalocyanine compound, a cyanine compound, a merocyanine compound, an oxonol compound, a polyamine compound, an indole compound, a pyrrole compound, a pyrazole compound, a polyarylene compound, a fused aromatic carbocyclic compound (e.g., a naphthalene derivative, an anthracene derivative, a phenanthrene derivative, a tetracene derivative, a pyrene derivative, a perylene derivative, or a fluoranthene derivative), or a nitrogen-containing heterocyclic compound, and the like can be used. Incidentally, the p-type organic semiconductor is not limited thereto, but as described above, organic compounds may be used as an organic semiconductor with donor properties so far as they have a smaller ionization potential than organic compounds which are used as an n-type compound (with acceptor properties).

The n-type organic semiconductor (compound) is an organic semiconductor with acceptor properties and refers to an organic compound chiefly represented by an electron transporting organic compound and having such properties that it is liable to accept electrons. In more detail, when two organic materials are brought into contact with each other and used, an organic compound having a larger electron affinity is referred to as the n-type organic semiconductor. In consequence, as for the organic compound with acceptor properties, any organic compounds can be used so far as they are an organic compound with electron accepting properties. Examples thereof include metal complexes having, as a ligand, a fused aromatic carbocyclic compound (e.g., a naphthalene derivative, an anthracene derivative, a phenanthrene derivative, a tetracene derivative, a pyrene derivative, a perylene derivative, or a fluoranthene derivative), a 5- to 7-membered heterocyclic compound containing a nitrogen atom, an oxygen atom, or a sulfur atom (for example, pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyraridine, pyrrolopyridine, thiadiazolopyridine, dibenzazepine, tribenzazepine, etc.), a polyarylene compound, a fluorenone compound, a cyclopentadiene compound, a silyl compound, or a nitrogen-containing heterocyclic compound, and the like. Incidentally, the n-type organic semiconductor is not limited thereto, but as described above, organic compounds may be used as an organic semiconductor with acceptor properties so far as they have a larger electron affinity than organic compounds which are used as a p-type compound (with donor properties).

Though any organic dyes may be used as the p-type organic semiconductor or n-type organic semiconductor, preferably, examples thereof include cyanine dyes, styryl dyes, hemicyanine dyes, merocyanine dyes (inclusive of zeromethine merocyanines (simple merocyanines)), trinuclear merocyanine dyes, tetranuclear merocyanine dyes, rhodacyanine dyes, complex cyanine dyes, complex merocyanine dyes, alopolar dyes, oxonol dyes, hemioxonol dyes, squarylium dyes, croconium dyes, azamethine dyes, coumarin dyes, arylidene dyes, anthraquinone dyes, triphenylmethane dyes, azo dyes, azomethine dyes, spiro compounds, metallocene dyes, fluorenone dyes, fulgide dyes, perylene dyes, perinone dyes, phenazine dyes, phenothiazine dyes, quinone dyes, diphenylmethane dyes, polyene dyes, acridine dyes, acridinone dyes, diphenylamine dyes, quinacridone dyes, quinophthalone dyes, phenoxazine dyes, phthaloperylene dye, diketopyrrolopyrrole dyes, dioxane dyes, porphyrin dyes, chlorophyll dyes, phthalocyanine dyes, metal complex dyes, and fused aromatic carbocyclic dyes (e.g., naphthalene derivatives, anthracene derivatives, phenanthrene derivatives, tetracene derivatives, pyrene derivative, perylene derivatives, or fluoranthene derivatives).

It is especially preferable to use, as the n-type organic semiconductor, a fullerene or a fullerene derivative each having excellent electron transporting properties. The fullerene as referred to herein indicates fullerene C₆₀, fullerene C₇₀, fullerene C₇₆, fullerene C₇₈, fullerene C₈₀, fullerene C₈₂, fullerene C₈₄, fullerene C₉₀, fullerene C₉₆, fullerene C₂₄₀, fullerene C₅₄₀, a mixed fullerene, or a fullerene nanotube; and the fullerene derivative as referred to herein indicates a compound obtained by adding a substituent to such a fullerene.

When the photoelectric conversion layer 22a contains a fullerene or a fullerene derivative, electrons emitted by the photoelectric conversion can be rapidly transported into the pixel electrode 21 or the counter electrode 23 through a fullerene molecule or a fullerene derivative molecule. When a passage of electrons is formed in a state where the fullerene molecules or fullerene derivative molecules lie in a row, the electron transporting properties are enhanced, whereby it becomes possible to realize high-speed response of the photoelectric conversion device. In order to achieve this, it is preferable that the photoelectric conversion layer 22a contains the fullerene or fullerene derivative in an amount of 40% or more. Indeed, when the amount of the fullerene or fullerene derivative is in excess, the amount of the p-type organic semiconductor becomes small, whereby the joined interface becomes small, whereby the exciton dissociation efficiency is lowered.

In the photoelectric conversion layer 22a, the use of a triarylamine compound described in Japanese Patent No. 4213832 or the like as the p-type organic semiconductor which is mixed together with the fullerene or fullerene derivative is especially preferable because it is possible to reveal a high SN ratio of the photoelectric conversion device. When the ratio of the fullerene or fullerene derivative within the photoelectric conversion layer 22a is in excess, the amount of the triarylamine compound becomes small, whereby the absorption amount of incident light is lowered. According to this, the photoelectric conversion efficiency is reduced, and therefore, a composition in which the ratio of the fullerene or fullerene derivative contained in the photoelectric conversion layer 22a is not more than 85% is preferable.

For the charge blocking layer 22b, an electron donating organic material can be used. Specifically, examples of a low molecular weight material which can be used include aromatic diamine compounds such as N,N′-bis(3-methylphenyl)-(1,1′-biphenyl)-4,4′-diamine (TPD), 4,4′-bis[N-(naphthyl)-N-phenyl-amino]biphenyl (α-NPD), etc., oxazole, oxadiazole, triazole, imidazole, imidazolone, stilbene derivatives, pyrazoline derivatives, tetrahydroimidazole, polyarylalkanes, butadiene, 4,4′,4″-tris(N-(3-methylphenyl)N-phenylamino)triphenylamine (m-MTDATA), porphyrin compounds such as porphine, copper tetraphenylporphine, phthalocyanine, copper phthalocyanine, titanium phthalocyanine oxide, etc., triazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, oxazole derivatives, styrylanthracene derivatives, fluorenone derivatives, hydrazone derivatives, silazane derivatives, and the like. Examples of a polymer material which can be used include polymers of phenylenevinylene, fluorene, carbazole, indole, pyrene, pyrrole, picoline, thiophene, acetylene, diacetylene, or the like, and derivatives thereof. It is also possible to use even a compound which is not an electron donating compound but has sufficient hole transporting properties.

It is also possible to use an inorganic material as the charge blocking layer 22b. Since an inorganic material is in general larger than an organic material in terms of dielectric constant 1, in the case of using an inorganic material in the charge blocking layer 22b, a large voltage is applied to the photoelectric conversion layer 22a, thereby enabling the photoelectric conversion efficiency to increase. Examples of a material which may be formed into the charge blocking layer 22b include calcium oxide, chromium oxide, copper chromium oxide, manganese oxide, cobalt oxide, nickel oxide, copper oxide, copper gallium oxide, copper strontium oxide, niobium oxide, molybdenum oxide, copper indium oxide, silver indium oxide, iridium oxide, and the like.

In the charge blocking layer 22b composed of plural layers, it is preferable that among the plural layers, the layer adjacent to the photoelectric conversion layer 22a is a layer made of the same material as the p-type organic semiconductor which is contained in the photoelectric conversion layer 22a. By also using the same p-type organic semiconductor in the charge blocking layer 22b, the formation of an intermediate level at an interface of the layer adjacent to the photoelectric conversion layer 22a is suppressed, whereby the dark current can be more suppressed.

In the case where the charge blocking layer 22b is a single layer, the layer can be a layer made of an inorganic material. In the case where the charge blocking layer 22b is composed of plural layers, one or two or more layers thereof can be formed as a layer made of an inorganic material.

### Example 1

The solid-state imaging device shown in FIG. 1 was fabricated. The pixel region was formed so as to have a size of ¼ inches, and the film thickness of the counter electrode was designed so as to have a resistance of 10 kΩ/□. In addition, the light receiving layer 22 was configured to have the sensitivity shown in FIG. 4, and 15 V of a counter voltage was impressed to the voltage supply section. The pixel electrode and the connecting section were constituted of TiN, and the solid-state imaging device was configured such that a potential difference between the counter electrode and the voltage supply section was not more than 100 mV.

### Example 2

Solid-state imaging devices were fabricated in the same manner as that in Example 1, except that the number and disposition regarding the connecting section 3 and the layout of the bias voltage supply line 4 were changed to the configurations shown in FIGS. 5, 6, 8, and 9, respectively.

### Comparative Example 1

A solid-state imaging device was fabricated in the same manner as that in Example 1, except that the number and disposition regarding the connecting section 3 and the layout of the bias voltage supply line 4 were changed to the configuration shown in FIG. 11.

All of the fabricated solid-state imaging devices were uniformly irradiated with light, and an average value of output in every divided area of 10×10 pixels was obtained. However, an output value of a distinct defective pixel was excluded from the subject of calculation of the average value.

As for all of the pixels, the average value of output was calculated and designated as a standard value (exclusive of an output value in a defective pixel), and a ratio of the average value of output in every divided area to the standard value {[(average value of output)÷ (standard value)]×100}(%) was calculated. A value obtained by subtracting a ratio of a divided area where the foregoing ratio was the smallest from 100% was defined as sensitivity unevenness of the solid-state imaging device. Results of the sensitivity unevenness of the respective solid-state imaging devices are shown in Table 1.

TABLE 1

| | | Sensitivity |
|---|---|---|
| | Disposition of connecting section | unevenness (%) |
| Example 1 | Adjacent to two sides which are opposing | 0.2 |
| | to each other in the pixel region | |
| Example 2 | Adjacent to two sides which are adjacent | 0.3 |
| | to each other in the pixel region | |
| Example 3 | Adjacent to one side in the pixel region | 0.5 |
| Example 4 | In the vicinity of two corners on a | 0.4 |
| | diagonal line in the pixel region | |
| Example 5 | In the vicinity of two corners which are | 0.5 |
| | adjacent to each other in the pixel region | |
| Comparative | In the vicinity of one corner in the pixel | 1.2 |
| Example 1 | region | |

In spite of the fact that the size of the pixel region and the resistance value of the counter electrode were controlled to such an extent that the voltage drop of the counter electrode could be ignored, in the solid-state imaging device shown in Comparative Example 1, the sensitivity unevenness was a large value as 1.2%. In the solid-state imaging devices of Examples 1 to 5, the sensitivity unevenness was not more than 0.5%, a value of which is not problematic from the standpoint of practical use, and hence, it was noted that the sensitivity unevenness was suppressed by the configuration according to the present invention.

Incidentally, the solid-state imaging device as described above can be used upon being mounted in an imaging apparatus such as digital cameras, digital video cameras, electronic endoscope systems, camera-equipped mobile phones, etc.

The present specification discloses the following matters.

The disclosed solid-state imaging device is one which comprises plural pixel electrodes two-dimensionally arranged above a substrate; a counter electrode constituted of a transparent electrically conductive oxide having a resistance of not more than 100 kΩ/□, which is formed at an upper layer of the plural pixel electrodes; a light receiving layer including a photoelectric conversion layer containing an organic material, which is formed between the plural pixel electrodes and the counter electrode; and a connecting section for undergoing electrical connection between a voltage supply line for supplying a bias voltage to be impressed to the counter electrode, wherein in a plan view, a rectangular region in which the plural pixel electrodes are arranged is defined as a pixel region; the pixel region has a size of not more than 5 inches; the connecting section is formed in a region which is a peripheral region outside the pixel region and which is made in the vicinity of at least one side among four sides of the pixel region and along the one side, or in a region in the vicinity of at least two corners among four corners of the pixel region; and the counter electrode is formed extending to above the connecting section.

The disclosed solid-state imaging device is one in which the connecting section is formed in the same layer as the pixel electrodes.

The disclosed solid-state imaging device is one in which the connecting section is configured to contain the same electrically conductive material as an electrically conductive material constituting the pixel electrode.

The disclosed solid-state imaging device is one in which the electrically conductive material contains at least one of TiN, W, Cr, ITO, Al, Cu, and AlCu.

The disclosed solid-state imaging device is one in which the connecting section is constituted of a different electrically conductive material from that of the counter electrode.

The disclosed solid-state imaging device is one in which the transparent electrically conductive oxide is ITO.

The disclosed solid-state imaging device is one in which the counter electrode has a transmittance of 95% or more.

The disclosed solid-state imaging device is one in which the counter electrode extends to above the connecting section while covering a side wall of the light receiving layer.

The disclosed solid-state imaging device is one in which the connecting section and the voltage supply line are electrically connected to each other in plural places.

The disclosed solid-state imaging device is one in which the connecting section is formed in each of regions adjacent to two sides among four sides of the pixel region and along each of these two sides in the peripheral region.

The disclosed solid-state imaging device is one in which the two sides are two sides which are opposing to each other.

The disclosed solid-state imaging device is one in which the two sides are two sides which are adjacent to each other.

The disclosed solid-state imaging device is one in which the connecting section is formed in each of regions adjacent to all of sides of the pixel region and along each of these sides in the peripheral region.

The disclosed solid-state imaging device is one in which the connecting section is formed in a region in the vicinity of each of two corners among four corners of the pixel region in the peripheral region.

The disclosed solid-state imaging device is one in which the two corners are two corners which are diagonal to each other.

The disclosed solid-state imaging device is one in which the two corners are two corners which are adjacent to each other.

The disclosed solid-state imaging device is one in which the connecting section is formed in a region in the vicinity of each of all of corners of the pixel region in the peripheral region.

The disclosed solid-state imaging device is one in which the voltage supply line is provided with a voltage supply section for supplying the bias voltage to the voltage supply line.

The disclosed solid-state imaging device is one in which an absolute value of the bias voltage is a value in the range of from 0 V to 30 V.

The disclosed solid-state imaging device is one in which a potential difference between a potential of the voltage supply section and a potential of the connecting section is not more than 0.1 V.

The disclosed solid-state imaging device is one in which a readout section for reading out a signal responsive to a charge collected by the pixel electrode is formed at the substrate, and the bias voltage is higher than a power supply voltage to be supplied to the readout section.

The disclosed solid-state imaging device is one in which the voltage supply section is a booster circuit for boosting the power supply voltage to produce the bias voltage.

The disclosed solid-state imaging device is one in which the voltage supply section is a pad to be connected to an external power supply.

The disclosed solid-state imaging device is one in which the voltage supply line is constituted of plural layers.

The disclosed imaging apparatus comprising the solid-state imaging device.

### INDUSTRIAL APPLICABILITY

According to the present invention, a solid-state imaging device capable of enhancing the captured image quality and an imaging apparatus can be provided.

While the invention has been described in detail and with reference to specific embodiments thereof, it will be apparent to one skilled in the art that various changes and modifications can be made therein without departing from the spirit and scope thereof.

The present application is based on a Japanese patent application filed on Sep. 27, 2010 (Japanese Patent Application No. 2010-216103), the contents of which are incorporated herein by reference.

### EXPLANATIONS OF LETTERS OR NUMERALS

1: Solid-state imaging device
2: Pixel region
3: Connecting section
4: Bias voltage supply line
5: Voltage supply section
6: Semiconductor substrate
21: Pixel electrode
22: Light receiving layer
23: Counter electrode

1. A solid-state imaging device comprising plural pixel electrodes two-dimensionally arranged above a substrate;
a counter electrode constituted of a transparent electrically conductive oxide having a resistance of not more than 100 kΩ/□, which is formed at an upper layer of the plural pixel electrodes;
a light receiving layer including a photoelectric conversion layer containing an organic material, which is formed between the plural pixel electrodes and the counter electrode; and
a connecting section for undergoing electrical connection between a voltage supply line for supplying a bias voltage to be impressed to the counter electrode, wherein
in a plan view, a rectangular region in which the plural pixel electrodes are arranged is defined as a pixel region;
the pixel region has a size of not more than 5 inches;
the connecting section is formed in a region which is a peripheral region outside the pixel region and which is made in the vicinity of at least one side among four sides of the pixel region and along the one side, or in a region in the vicinity of at least two corners among four corners of the pixel region; and
the counter electrode is formed extending to above the connecting section.

2. The solid-state imaging device as claimed in claim 1, wherein the connecting section is formed in same layer as the pixel electrodes.

3. The solid-state imaging device as claimed in claim 2, wherein the connecting section is configured to contain same electrically conductive material as an electrically conductive material constituting the pixel electrode.

4. The solid-state imaging device as claimed in claim 3, wherein the electrically conductive material contains at least one of TiN, W, Cr, ITO, Al, Cu and AlCu.

5. The solid-state imaging device as claimed in claim 1, wherein the connecting section is constituted of a different electrically conductive material from that of the counter electrode.

6. The solid-state imaging device as claimed in claim 1, wherein the transparent electrically conductive oxide is ITO.

7. The solid-state imaging device as claimed in claim 1, wherein the counter electrode has a transmittance of 95% or more.

8. The solid-state imaging device as claimed in claim 1, wherein the counter electrode extends to above the connecting section while covering a side wall of the light receiving layer.

9. The solid-state imaging device as claimed in claim 1, wherein the connecting section and the voltage supply line are electrically connected to each other in plural places.

10. The solid-state imaging device as claimed in claim 1, wherein the connecting section is formed in each of regions adjacent to two sides among four sides of the pixel region and along each of the two sides in the peripheral region.

11. The solid-state imaging device as claimed in claim 10, wherein the two sides are two sides which are opposing to each other.

12. The solid-state imaging device as claimed in claim 10, wherein the two sides are two sides which are adjacent to each other.

13. The solid-state imaging device as claimed in claim 1, wherein the connecting section is formed in each of regions adjacent to all of sides of the pixel region and along each of these sides in the peripheral region.

14. The solid-state imaging device as claimed in claim 1, wherein the connecting section is formed in a region in the vicinity of each of two corners among four corners of the pixel region in the peripheral region.

15. The solid-state imaging device as claimed in claim 14, wherein the two corners are two corners which are diagonal to each other.

16. The solid-state imaging device as claimed in claim 14, wherein the two corners are two corners which are adjacent to each other.

17. The solid-state imaging device as claimed in claim 1, wherein the connecting section is formed in a region in the vicinity of each of all of corners of the pixel region in the peripheral region.

18. The solid-state imaging device as claimed in claim 1, wherein the voltage supply line is provided with a voltage supply section for supplying the bias voltage to the voltage supply line.

19. The solid-state imaging device as claimed in claim 18, wherein an absolute value of the bias voltage is a value in a range of from 0 V to 30 V.

20. The solid-state imaging device as claimed in claim 18, wherein a potential difference between a potential of the voltage supply section and a potential of the connecting section is not more than 0.1 V.

21. The solid-state imaging device as claimed in claim 18, wherein a readout section for reading out a signal responsive to a charge collected by the pixel electrode is formed at the substrate, and the bias voltage is higher than a power supply voltage to be supplied to the readout section.

22. The solid-state imaging device as claimed in claim 21, wherein the voltage supply section is a booster circuit for boosting the power supply voltage to produce the bias voltage.

23. The solid-state imaging device as claimed in claim 18, wherein the voltage supply section is a pad to be connected to an external power supply.

24. The solid-state imaging device as claimed in claim 1, wherein the voltage supply line is constituted of plural layers.

25. An imaging apparatus comprises the solid-state imaging device according to claim 1.
